(19) United States
(12) Patent Application Publication
(10) Pub. No.: US 2026/0216996 A1
(43) Pub. Date: Jul. 30, 2026

(54) COMPOSITE WAFER AND METHOD FOR PRODUCING COMPOSITE WAFER

(71) Applicant: NGK INSULATORS, LTD., Nagoya-shi (JP)

(72) Inventors: Jungo KONDO, Kasugai-shi (JP); Kentaro TANI, Nagoya-shi (JP); Tomoyoshi TAI, Inazawa-shi (JP); Shun HOSONO, Nagoya-shi (JP)

(21) Appl. No.: 19/629,572

(22) Filed: Mar. 26, 2026

Related U.S. Application Data
(63) Continuation of application No. PCT/JP2024/034690, filed on Sep. 27, 2024.

(30) Foreign Application Priority Data
Sep. 28, 2023 (JP) 2023-167810

(51) Int. Cl. B32B 9/04; B32B 9/00; B32B 17/06; B32B 37/18; B32B 38/00

(52) U.S. Cl. CPC B32B 9/04; B32B 9/005; B32B 17/06; B32B 37/18; B32B 38/0008; B32B 2307/7376; B32B 2309/105; B32B 2313/00; B32B 2315/02; B32B 2315/08; B32B 2457/14; B32B 2551/00

(57) ABSTRACT

A composite wafer includes in this order: a support substrate; an amorphous layer; and a SiO₂-containing substrate. The amorphous layer is in contact with a first adjacent layer and a second adjacent layer, and includes an element included in each of the first adjacent layer and the second adjacent layer. A composite wafer of another embodiment of the present disclosure includes in this order: a support substrate; an amorphous layer; and a SiO₂-containing substrate having a OH group content of 100 ppm or less. The amorphous layer is in contact with a first adjacent layer and a second adjacent layer, and includes an element included in each of the first adjacent layer and the second adjacent layer. A method of producing a composite wafer of an embodiment of the present disclosure includes directly joining a support substrate and a SiO₂-containing bulk.

### CROSS-REFERENCE TO RELATED APPLICATIONS

This application is a continuation under 35 U.S.C. 120 of International Application PCT/JP2024/034690 having the International Filing Date of September 27, 2024 and having the benefit of the earlier filing date of Japanese Application No. 2023-167810 filed on September 28, 2023. Each of the identified applications is fully incorporated herein by reference.

### BACKGROUND OF THE INVENTION

### 1. Field of the Invention

The present disclosure relates to a composite wafer and a method of producing a composite wafer.

### 2. Description of the Related Art

A composite wafer can exhibit characteristics that cannot be exhibited by a single-layer wafer by laminating wafers containing different materials. Accordingly, the composite wafer has been widely used in various fields, such as a semiconductor and an electronic device.

### Citation List

### Patent Literature

PTL 1 JP 2013-30617 A

### SUMMARY OF THE INVENTION

Meanwhile, warpage and breakage due to heating are liable to occur depending on materials for forming a wafer, and hence lamination with any other wafer may become difficult. Accordingly, a functional layer to be formed on a support substrate may be limited. Accordingly, a composite wafer that can achieve lamination in more various combinations has been required.

1. According to one embodiment of the present disclosure, there is provided a composite wafer, including in this order: a support substrate; an amorphous layer; and a SiO₂-containing substrate, wherein the amorphous layer is in contact with a first adjacent layer and a second adjacent layer, and includes an element included in each of the first adjacent layer and the second adjacent layer.

2. According to another embodiment of the present disclosure, there is provided a composite wafer, including in this order: a support substrate; an amorphous layer; and a SiO₂-containing substrate having a OH group content of 100 ppm or less, wherein the amorphous layer is in contact with a first adjacent layer and a second adjacent layer, and includes an element included in each of the first adjacent layer and the second adjacent layer.

3. In the composite wafer according to the above-mentioned item 1 or 2, the first adjacent layer may be the support substrate, and the second adjacent layer may be the SiO₂-containing substrate.

4. The composite wafer according to any one of the above-mentioned items 1 to 3 may further include an intermediate layer, wherein at least one of the first adjacent layer or the second adjacent layer may be the intermediate layer.

5. In the composite wafer according to any one of the above-mentioned items 1 to 4, the SiO₂-containing substrate has a thickness of 5 μm or more.

6. In the composite wafer according to any one of the above-mentioned items 1 to 5, the support substrate may be formed of at least one kind selected from the group consisting of: silicon; indium phosphorus; gallium nitride; gallium arsenide; aluminum nitride; and diamond.

7. In the composite wafer according to any one of the above-mentioned items 1, 3 to 6, the SiO₂-containing substrate may be formed of synthetic quartz glass, quartz glass, oxynitride glass, borosilicate glass, soda-based glass, or crystal.

8. In the composite wafer according to any one of the above-mentioned items 1 and 3 to 7, the SiO₂-containing substrate may have a thin-layer processed surface on a surface opposite to a surface joined to the support substrate.

9. The composite wafer according to the above-mentioned item 8 may further include a functional layer laminated on the thin-layer processed surface of the SiO₂-containing substrate.

10. In the composite wafer according to the above-mentioned item 9, the functional layer may be formed of at least one kind selected from the group consisting of: silicon nitride; niobium pentoxide; tantalum pentoxide; aluminum oxide; silicon; indium phosphorus; gallium nitride; aluminum nitride; silicon carbide; gallium oxide; gallium arsenide; barium titanate; sapphire; lead zirconate titanate; lead lanthanum zirconate titanate; gallium phosphide; and potassium tantalate niobate.

11. In the composite wafer according to the above-mentioned item 2, the SiO₂-containing substrate may be at least one kind selected from the group consisting of: synthetic quartz glass; fused quartz glass; and sol-gel glass.

12. In the composite wafer according to the above-mentioned item 2 or 3 to 6, the SiO₂-containing substrate may have a thin-layer processed surface on a surface opposite to a surface joined to the support substrate.

13. The composite wafer according to the above-mentioned item 12 may further include a functional layer laminated on the thin-layer processed surface of the SiO₂-containing substrate.

14. In the composite wafer according to the above-mentioned item 13, the functional layer may be formed of at least one kind selected from the group consisting of: silicon nitride; niobium pentoxide; tantalum pentoxide; aluminum oxide; silicon; indium phosphorus; gallium nitride; aluminum nitride; silicon carbide; gallium oxide; gallium arsenide; barium titanate; sapphire; lead zirconate titanate; lead lanthanum zirconate titanate; gallium phosphide; potassium tantalate niobate; lithium niobate; and lithium tantalate.

15. In the composite wafer according to any one of the above-mentioned items 1 to 14, a thermal expansion coefficient αs of the support substrate and a thermal expansion coefficient αg of the SiO₂-containing substrate may satisfy a relationship of 0.05≤αg/αs≤1.5.

16. In the composite wafer according to the above-mentioned items 9, 10, 13 and 14, a thermal expansion coefficient αg of the SiO₂-containing substrate and a thermal expansion coefficient αf of the functional layer may satisfy a relationship of 0.5≤αf/αg≤10.

17. According to another aspect of an embodiment of the present disclosure, there is provided a method of producing a composite wafer. The method of producing a composite wafer includes directly joining a support substrate and a SiO₂-containing bulk.

18. According to still another aspect of an embodiment of the present disclosure, there is provided a method of producing a composite wafer. The method of producing a composite wafer includes: forming an intermediate layer on at least one of a support substrate or a SiO₂-containing bulk; and directly joining: the intermediate layer formed on the support substrate and the SiO₂-containing bulk; the intermediate layer formed on the SiO₂-containing bulk and the support substrate; or the intermediate layer formed on the support substrate and the intermediate layer formed on the SiO₂-containing bulk.

19. The method of producing a composite wafer according to the above-mentioned item 17 or 18 may further include producing a SiO₂-containing substrate by thinning a SiO₂-containing bulk joined to a support substrate.

20. In the method of producing a composite wafer according to any one of the above-mentioned items 17 to 19, the SiO₂-containing bulk may have a thickness of 100 μm or more.

21. The method of producing a composite wafer according to any one of the above-mentioned items 17 to 20 may further include forming a functional layer on the SiO₂-containing substrate.

22. In the method of producing a composite wafer according to any one of the above-mentioned items 17 to 21, the SiO₂-containing bulk has a OH group content of 100 ppm or less.

According to the embodiment of the present disclosure, the composite wafer having excellent heat resistance and the method of producing a composite wafer can be provided. Warpage and breakage can be suppressed in the composite wafer of an embodiment of the present disclosure even when the composite wafer is heated at higher temperature. As a result, a composite wafer having a functional layer with higher functionality can be provided. In addition, the functional layer can be formed by bonding because occurrence of warpage is suppressed. In addition, a decrease in joining strength between the functional layer and the SiO₂-containing substrate can be suppressed.

### BRIEF DESCRIPTION OF THE DRAWINGS

FIG. 1 is a schematic cross-sectional view of a composite wafer of an embodiment of the present disclosure.

FIG. 2 is a schematic cross-sectional view of a composite wafer of another embodiment of the present disclosure.

FIG. 3 is a schematic cross-sectional view of a composite wafer of still another embodiment of the present disclosure.

### DESCRIPTION OF THE EMBODIMENTS

### A. Overall Configuration of Composite Wafer

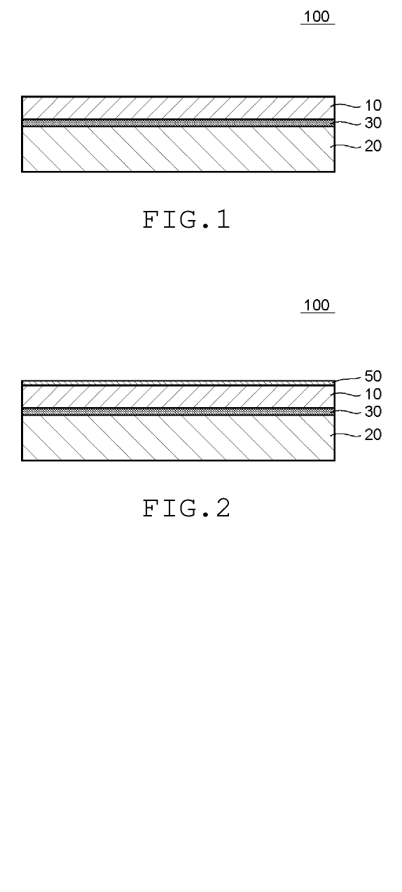

FIG. 1 is a schematic cross-sectional view of a composite wafer of an embodiment of the present disclosure. A composite wafer 100 of the illustrated example includes a support substrate 20, an amorphous layer 30, and a SiO₂-containing substrate 10. In one embodiment, the SiO₂-containing substrate 10 is a SiO₂-containing substrate having a OH group content of 100 ppm or less. The amorphous layer 30 is in contact with a first adjacent layer and a second adjacent layer. In the illustrated example, the first adjacent layer is the support substrate 20, and the second adjacent layer is the SiO₂-containing substrate 10. In the illustrated example, the amorphous layer 30 is a layer formed by directly joining the support substrate 20 and the SiO₂-containing substrate 10. In this embodiment, the amorphous layer 30 has an amorphous structure, and includes an element for forming the support substrate 20 serving as the first adjacent layer and an element for forming the SiO₂-containing substrate 10 serving as the second adjacent layer. In addition, typically, the amorphous layer 30 may further include an atom species (typically, argon, neon, krypton, helium, nitrogen, or xenon) for forming a neutral atom beam to be used for the direct joining. In the illustrated example, the surface of the amorphous layer 30 on a SiO₂-containing substrate 10 side may form a well-defined interface with the SiO₂-containing substrate 10 (that is, the second adjacent layer). Similarly, the surface of the amorphous layer 30 on a support substrate 20 side may form a well-defined interface with the support substrate 20 (that is, the first adjacent layer). In one embodiment, the SiO₂-containing substrate 10 may be a layer having an amorphous structure such as quartz glass. Also in this embodiment, when the second adjacent layer is the SiO₂-containing substrate, an interface between the SiO₂-containing substrate 10 and the amorphous layer 30 may be clearly distinguished. For example, when the composite wafer 100 in which the amorphous layer 30 is formed is observed with a transmission electron microscope at any appropriate magnification, the interface of the amorphous layer 30 on the SiO₂-containing substrate 10 side and the interface of the amorphous layer 30 on the support substrate 20 side may be observed.

The composite wafer 100 may further include an

intermediate layer (not shown). The intermediate layer may be arranged at any appropriate position. Specifically, the intermediate layer may be arranged between the support substrate 20 and the amorphous layer 30, the intermediate layer may be arranged between the amorphous layer 30 and the SiO₂-containing substrate 10, or the intermediate layers may be arranged between the support substrate 20 and the amorphous layer 30, and between the amorphous layer 30 and the SiO₂-containing substrate 10, respectively. When the composite wafer includes the intermediate layer, the amorphous layer may be formed by directly joining: the intermediate layer and the support substrate; the intermediate layer and the SiO₂-containing substrate; or the intermediate layer and another intermediate layer. In one embodiment, the first adjacent layer and/or the second adjacent layer is the intermediate layer. When the first adjacent layer and/or the second adjacent layer is the intermediate layer, the amorphous layer 30 may include an element included in the intermediate layer. For example, when the first adjacent layer is the intermediate layer and the second adjacent layer is the support substrate, the amorphous layer 30 may include an element included in the intermediate layer and an element included in the support substrate. In addition, when the first adjacent layer is the SiO₂-containing substrate and the second adjacent layer is the intermediate layer, the amorphous layer 30 may include an element included in the SiO₂-containing substrate and an element included in the intermediate layer.

Further, when the first adjacent layer and the second adjacent layer are the intermediate layers, the amorphous layer 30 may include an element included in the intermediate layer serving as the first adjacent layer and an element included in the intermediate layer serving as the second adjacent layer. When the first adjacent layer and the second adjacent layer are the intermediate layers, those intermediate layers may be formed of materials including the same element or may be formed of materials including different elements.

FIG. 2 is a schematic cross-sectional view of a composite wafer of another embodiment of the present disclosure. In the composite wafer 100 of the illustrated example, the amorphous layer 30 is formed by directly joining the support substrate 20 and the SiO₂-containing substrate 10. In the illustrated example, the first adjacent layer is the support substrate 20, and the second adjacent layer is the SiO₂-containing substrate. In the illustrated example, the SiO₂-containing substrate 10 has a thin-layer processed surface 50 on a surface opposite to a surface joined to the support substrate 20 (that is, the surface of the SiO₂-containing substrate 10 free from being joined to the support substrate 20). The thin-layer processed surface 50 may be produced by thinning a raw material for the SiO₂-containing substrate (e.g., a SiO₂-containing bulk) through polishing or the like in the process of producing the composite wafer.

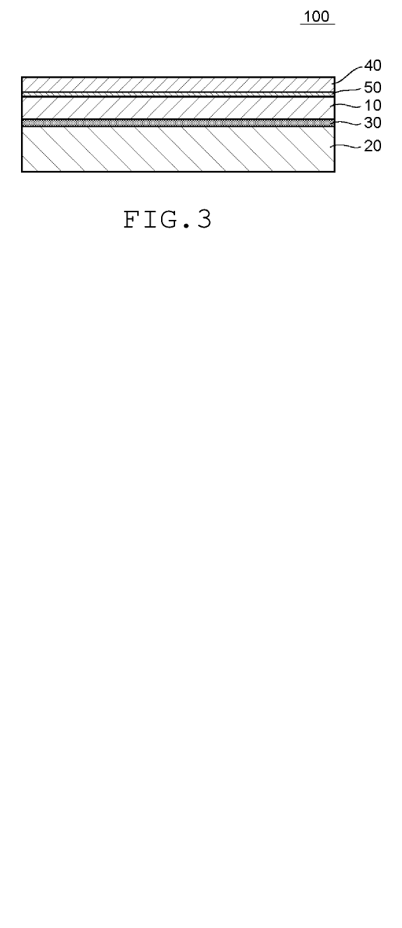

FIG. 3 is a schematic cross-sectional view of a composite wafer according to still another embodiment of the present disclosure. In the composite wafer 100 of the illustrated example, the amorphous layer 30 is formed by directly joining the support substrate 20 and the SiO₂-containing substrate 10. In the illustrated example, the first adjacent layer is the support substrate 20, and the second adjacent layer is the SiO₂-containing substrate. The SiO₂-containing substrate 10 has the thin-layer processed surface 50 on a surface opposite to a surface joined to the support substrate 20 (that is, the surface of the SiO₂-containing substrate 10 free from being joined to the support substrate 20). In this embodiment, a functional layer 40 is further laminated on the surface of the SiO₂-containing substrate 10 free from being joined to the support substrate 20 (that is, the thin-layer processed surface 50). The functional layer 40 may be laminated on the SiO₂-containing substrate 10 by any appropriate method. For example, the functional layer 40 may be directly formed on the SiO₂-containing substrate 10, or the functional layer 40 formed on any appropriate base material may be transferred (rebonded) to the SiO₂-containing substrate 10. When the functional layer 40 is rebonded to the SiO₂-containing substrate 10, the functional layer 40 and the SiO₂-containing substrate 10 may be laminated via any appropriate joining layer or may be directly joined. When the functional layer 40 and the SiO₂-containing substrate 10 are directly joined, the amorphous layer may be formed between the functional layer 40 and the SiO₂-containing substrate 10 (not shown). When the functional layer is laminated by rebonding, the base material used in the formation of the functional layer may be peeled off, may be removed by any appropriate treatment, such as polishing or smart cutting, or may be used as it is as a layer for forming the composite wafer.

As described above, in one embodiment, in the composite wafer of the embodiment of the present disclosure, the amorphous layer 30 is formed by directly joining the first adjacent layer and the second adjacent layer (e.g., the support substrate 20 and the SiO₂-containing substrate 10). That is, the composite wafer is a composite wafer obtained by directly joining the first adjacent layer and the second adjacent layer (e.g., the support substrate 20 and the SiO₂-containing substrate 10). In addition, the composite wafer 100 has the thin-layer processed surface 50, and the SiO₂-containing substrate 10 is a layer formed by thinning a raw material for a SiO₂-containing substrate (e.g., a SiO₂-containing bulk) through polishing or the like. In the composite wafer of the embodiment of the present disclosure, the warpage and breakage of the wafer can be suppressed even when the wafer is subjected to high temperature. Accordingly, a composite wafer having excellent heat resistance can be provided. Further, the functional layer can be formed and laminated at higher temperature because the composite wafer has excellent heat resistance. Impurities and the like included in the functional layer are removed by forming the functional layer at high temperature, and hence a functional layer having excellent crystallinity can be formed. In addition, the density of the functional layer can be improved. As a result, a composite wafer having higher quality can be provided.

A ratio (αg/αs) between a thermal expansion coefficient αs of the support substrate 20 and a thermal expansion coefficient αg of the SiO₂-containing substrate 10 preferably satisfies the relationship of 0.05≤αg/αs≤1.5. The ratio more preferably satisfies the relationship of 0.10≤αg/αs≤1.2, and still more preferably satisfies the relationship of 0.15≤αg/αs≤1.0. When the ratio αg/αs falls within the above-mentioned ranges, a composite wafer having more excellent heat resistance can be provided.

A ratio (αf/αg) between the thermal expansion coefficient αg of the SiO₂-containing substrate 10 and a thermal expansion coefficient αf of the functional layer 40 preferably satisfies the relationship of 0.5≤αf/αg≤10. The ratio more preferably satisfies the relationship of 0.6≤αf/αg≤9, and still more preferably satisfies the relationship of 0.7≤αf/αg≤8. When the ratio αf/αg falls within the above-mentioned ranges, a composite wafer having more excellent heat resistance can be provided.

The composite wafer 100 may further include any appropriate layer. The kinds, functions, number, combination, arrangement, and the like of such layers may be appropriately set in accordance with purposes.

### B. Support Substrate

Any appropriate substrate may be used as the support substrate 20. The support substrate may be formed of a single crystal or a polycrystal. In addition, the support substrate may be formed of a metal. Any appropriate material may be used as a material for forming the support substrate. Specific examples thereof include silicon (Si), indium phosphorus (InP), gallium nitride (GaN), gallium arsenide (GaAs), aluminum nitride (AlN), diamond, silicon carbide (SiC), gallium oxide (Ga₂O₃), and sapphire (Al₂O₃). Of those, silicon (Si), indium phosphorus (InP), gallium nitride (GaN), gallium arsenide (GaAs), aluminum nitride (AlN), or diamond may be preferably used.

The thermal expansion coefficient αs of the support substrate 20 may be set to any appropriate value. The thermal expansion coefficient of the support substrate 20 may be set so that the ratio (αg/αs) between the thermal expansion coefficient αs of the support substrate 20 and the thermal expansion coefficient αg of the SiO₂-containing substrate 10 falls within the above-mentioned ranges. The thermal expansion coefficient αs of the support substrate is preferably from 1.0 ppm/°C to 4.0 ppm/°C, more preferably from 1.5 ppm/°C to 3.5 ppm/°C, still more preferably from 2.0 ppm/°C to 3.0 ppm/°C. For example, thermal expansion coefficients of the materials to be used as the materials for forming the support substrate are as follows: silicon (2.6 ppm/°C); indium phosphorus (4.5 ppm/°C); gallium nitride (5.6 ppm/°C); gallium arsenide (6.0 ppm/°C); aluminum nitride (4.6 ppm/°C); and diamond (0.7 ppm/°C). When the thermal expansion coefficient αs of the support substrate falls within the above-mentioned ranges, a composite wafer having more excellent heat resistance can be provided. The thermal expansion coefficient of the support substrate may be measured by any appropriate method. For example, the thermal expansion coefficient may be measured with a thermomechanical analyzer (TMA).

A density of the support substrate 20 may be set to any appropriate value. The density of the support substrate is preferably from 1.5 g/cm³ to 4.0 g/cm³, more preferably from 2.0 g/cm³ to 3.5 g/cm³, still more preferably from 2.2 g/cm³ to 3.0 g/cm³. For example, density of the materials to be used as the materials for forming the support substrate are as follows: silicon (2.3 g/cm³); indium phosphorus (4.79 g/cm³); gallium nitride (6.15 g/cm³); gallium arsenide (5.31 g/cm³); aluminum nitride (3.26 g/cm³); and diamond (3.52 g/cm³). When the density of the support substrate falls within the above-mentioned ranges, a composite wafer having more excellent heat resistance can be provided. The density of the support substrate may be measured by any appropriate method. For example, the density may be measured by density measurement using a pycnometer specified in JIS Z 8807.

Any appropriate thickness may be adopted as a thickness of the support substrate. The thickness of the support substrate is, for example, from 100 μm to 1,000 μm.

The composite wafer of the embodiment of the present disclosure may be obtained by directly joining a support substrate and a SiO₂-containing bulk as described later. When the support substrate is silicon (Si), a layer containing SiO₂ (glass layer) may be formed on the support substrate by thermal oxidation treatment. When the layer containing SiO₂ is formed by the thermal oxidation treatment, an entire exposed portion of a support substrate surface may be the layer containing SiO₂. Accordingly, the layer containing SiO₂ may be formed also in a part except a predetermined part. When the layer containing SiO₂ is formed by the thermal oxidation treatment, inherent stress due to a difference in thermal expansion coefficient between silicon and

the layer containing SiO₂ under a room temperature state may remain because thermal oxidation is typically performed at a temperature of from 800°C to 1,200°C. Thus, performance may significantly deteriorate because of the removal of the layer containing SiO₂ except the predetermined part and/or because of an influence of residual stress due to a change in layer structure. In addition, warpage of the composite wafer may occur. Accordingly, when the functional layer is formed by the bonding, it may become difficult to bring the SiO₂-containing substrate and the functional layer into close contact with each other. In addition, even when the functional layer is formed by bonding, joining strength may decrease because of remaining internal stress, and peeling of a joint portion may occur. In the composite wafer of the embodiment of the present disclosure, the first adjacent layer and the second adjacent layer (e.g., the support substrate and the SiO₂-containing substrate) are laminated via an amorphous layer formed by direct joining, and the composite wafer is free of the layer containing SiO₂ (glass layer) on any other surface of the support substrate, such as a side surface or a surface to which the SiO₂-containing substrate is free from being joined. The influence of the residual stress at the time of the joining of the support substrate and the SiO₂-containing substrate can be suppressed in the composite wafer of the embodiment of the present disclosure. As a result, the functional layer can also be formed by the bonding.

### C. SiO₂-containing Substrate

Any appropriate substrate containing SiO₂ may be used as the SiO₂-containing substrate 10. The SiO₂-containing substrate may have a crystalline structure or may have an amorphous structure. As described above, the SiO₂-containing substrate can be clearly distinguished from an amorphous layer formed by direct joining even when the SiO₂-containing substrate has an amorphous structure. A material for forming the SiO₂-containing substrate is, for example, synthetic quartz glass, quartz glass (natural quartz glass), oxynitride glass, borosilicate glass, soda-based glass, crystal, and chalcogenide glass. Of those, synthetic quartz glass, quartz glass, oxynitride glass, borosilicate glass, soda-based glass, or crystal is preferred, and synthetic quartz glass or quartz glass is more preferred. In one embodiment, synthetic quartz glass having a reduced amount of OH groups may be used as the synthetic quartz glass. When the synthetic quartz glass having a reduced amount of OH groups is used, a composite wafer having a low loss at a high frequency (e.g., 30 GHz or more) can be provided. In this embodiment, a OH group content of the synthetic quartz glass is, for example, 100 ppm or less.

As described above, in one embodiment, the SiO₂-containing substrate has a OH group content of 100 ppm or less. When the OH group content of the SiO₂-containing substrate is 100 ppm or less, light absorption of the SiO₂-containing substrate can be suppressed. The OH group content of the SiO₂-containing substrate is preferably 50 ppm or less, more preferably 20 ppm or less. The OH group content of the SiO₂-containing substrate is preferably as low as possible, and is, for example, 0.1 ppm or more. The OH group content of the SiO₂-containing substrate may be measured by any appropriate method.

Synthetic quartz glass, fused quartz glass, and sol-gel glass are each preferably used as the SiO₂-containing substrate having a OH group content of 100 ppm or less. The OH group content of the SiO₂-containing substrate can be reduced when each of the synthetic quartz glass, the fused quartz glass, and the sol-gel glass is used. Synthetic quartz glass having a OH group content of 100 ppm or less may be produced by any appropriate method. For example, synthetic quartz glass having a OH group content of 100 ppm or less may be produced by slip casting. The slip casting can suppress contamination of OH groups and can cope with complex substrate shapes. The slip casting typically includes: preparing a mold in accordance with a shape of a substrate; pouring a slurry including raw material powder, and a predetermined dispersant and a predetermined dispersion medium into the mold; and firing the slurry after solidifying the poured slurry in the mold. When the synthetic quartz glass is produced as described above, the contamination of OH groups can be suppressed as much as possible because silica or alumina is used as the raw material powder. The slip casting may be performed by, for example, a procedure described in WO 2018/100775 A1.

In addition, in the method of producing synthetic quartz glass, the synthetic quartz glass may be produced by using a material having a small OH group content. Examples of the method of producing synthetic quartz glass include: (I) a direct method including subjecting silicon tetrachloride (SiCl₄) to a reaction in a flame of oxygen and hydrogen to generate silica particles, and melting the silica particles at high temperature to form glass; (II) a soot method including subjecting silicon tetrachloride (SiCl₄) to a reaction in a flame of oxygen and hydrogen to generate silica particles, and depositing the silica particles at low temperature, followed by sintering to form glass (OH group content of the SiO₂-containing substrate to be obtained: 1 ppm to 200 ppm); and (III) a plasma method including producing a silica porous body from silicon tetrachloride (SiCl₄) by thermal oxidative decomposition or hydrolysis, and sintering and vitrifying the silica porous body (OH group content of the SiO₂-containing substrate to be obtained: less than 5 ppm). Quartz glass having an extremely high purity can be obtained by the direct method. Quartz glass having a purity higher than that in the direct method can be obtained by the soot method. The OH group content can be further reduced, and hence heat resistance of quartz glass to be obtained can be improved by an electric melting method. In addition, the OH group content may be reduced by performing reduction treatment with thionyl chloride or the like or by performing plasma firing in the production process of synthetic quartz glass.

Examples of the method of producing fused quartz glass include: an electric melting method including melting quartz powder by heat of an electric furnace or plasma to produce quartz glass (OH group content of the SiO₂-containing substrate to be obtained: less than 10 ppm); and an oxyhydrogen flame melting method including melting quartz powder using a high-temperature flame generated by a reaction of oxygen and hydrogen to form quartz glass. An example of the method of producing sol-gel glass is a sol-gel method including producing a silica porous body from a silicon alkoxide, and sintering and vitrifying the silica porous body (OH group content of the SiO₂-containing substrate to be obtained: 1 ppm to 200 ppm).

A thickness of the SiO₂-containing substrate is preferably 0.1 μm or more, more preferably from 2 μm to 15 μm, still more preferably from 5 μm to 11 μm. When the thickness of the SiO₂-containing substrate falls within the above-mentioned ranges, a composite wafer having more excellent heat resistance can be provided. Accordingly, when a functional layer is further formed, the functional layer can be formed at higher temperature. When the functional layer is formed at high temperature, a functional layer having higher functionality (e.g., a higher density or a higher purity) can be formed. A material for forming the functional layer is generally hard, and hence, when a surface to be rebonded is not flat, it may become difficult to bring bonding surfaces into close contact with each other. Warpage can be further suppressed in the composite wafer of the embodiment of the present disclosure. As a result, the functional layer can also be formed by transfer (rebonding). When the SiO₂-containing substrate is a SiO₂-containing substrate having a OH group content of 100 ppm or less, the thickness thereof may be, for example, from 0.1 μm to 15 μm, and is preferably from 2 μm to 11 μm, more preferably from 4 μm to 10 μm.

The thermal expansion coefficient αg of the SiO₂-containing substrate 10 may be set to any appropriate value. The thermal expansion coefficient of the SiO₂-containing substrate may be preferably set so that: the ratio (αg/αs) between the thermal expansion coefficient αs of the support substrate 20 and the thermal expansion coefficient αg of the SiO₂-containing substrate 10 satisfies the relationship of 0.05≤αg/αs≤1.5; and the ratio (αf/αg) between the thermal expansion coefficient αg of the SiO₂-containing substrate 10 and the thermal expansion coefficient αf of the functional layer 40 satisfies the relationship of 0.5≤αf/αg≤10. The thermal expansion coefficient αg of the SiO₂-containing substrate is preferably from 0.1 ppm/°C to 20 ppm/°C, more preferably from 0.2 ppm/°C to 18 ppm/°C, still more preferably from 0.5 ppm/°C to 15 ppm/°C. When the thermal expansion coefficient αg of the SiO₂-containing substrate falls within the above-mentioned ranges, a composite wafer having more excellent heat resistance can be provided. For example, thermal expansion coefficients of the materials to be used as the materials for forming the SiO₂-containing substrate are as follows: synthetic quartz glass (0.5 ppm/°C); quartz glass (natural quartz glass) (0.1 ppm/°C); borosilicate glass (5.2 ppm/°C); soda-based glass (soda-lime glass, 8.5 ppm/°C); crystal (z-axis: 7.48 ppm/°C, x-axis and y-axis: 13.71 ppm/°C); and chalcogenide glass (14 ppm/°C). The thermal expansion coefficient of the SiO₂-containing substrate may be measured by any appropriate method. For example, the thermal expansion coefficient may be measured with a thermomechanical analyzer (TMA).

A density of the SiO₂-containing substrate 10 may be set to any appropriate value. The density of the SiO₂-containing substrate is preferably from 1.5 g/cm³ to 4.0 g/cm³, more preferably from 2.0 g/cm³ to 3.5 g/cm³, still more preferably from 2.2 g/cm³ to 3.0 g/cm³. When the density of the SiO₂-containing substrate falls within the above-mentioned ranges, a composite wafer having more excellent heat resistance can be provided. For example, densities of the materials to be used as the materials for forming the SiO₂-containing substrate are as follows: synthetic quartz glass (2.2 g/cm³); quartz glass (natural quartz glass) (2.19 g/cm³); borosilicate glass (2.3 g/cm³); soda-based glass (soda-lime glass, 2.5 g/cm³); crystal (2.65 g/cm³); and chalcogenide glass (4.5 g/cm³). The density of the SiO₂-containing substrate may be measured by any appropriate method. For example, the density may be measured by density measurement using a pycnometer specified in JIS Z 8807.

The SiO₂-containing substrate preferably has a thin-layer processed surface. For example, a SiO₂-containing substrate having a thin-layer processed surface that is a mirror surface having a thickness of 10 μm and a surface roughness Ra of 0.1 nm may be obtained by grinding a plate-like SiO₂-containing material (e.g., a SiO₂-containing bulk) having a thickness of 500 μm with a grinder, and performing high-precision polishing by lap polishing or chemical mechanical polishing (CMP). The composite wafer of the embodiment of the present disclosure may be obtained by, for example, directly joining the support substrate and the SiO₂-containing bulk. The SiO₂-containing bulk is thick, and hence it is difficult to use the SiO₂-containing bulk as it is in the composite wafer. Accordingly, thinning may be performed to a predetermined thickness by any appropriate method. A method for the thinning may be, for example, polishing or smart cutting. In one embodiment, a SiO₂-containing substrate on which a thin-layer processed surface is formed may be obtained by polishing the SiO₂-containing bulk.

### D. Amorphous Layer

As described above, the amorphous layer 30 has an amorphous structure, and includes an element for forming the first adjacent layer (e.g., the support substrate 20) and an element for forming the second adjacent layer (e.g., the SiO₂-containing substrate 10) . For example, the amorphous layer may include Si and oxygen as elements when the support substrate serving as the first adjacent layer is silicon and the SiO₂-containing substrate serving as the second adjacent layer is quartz glass. When the first adjacent layer and/or the second adjacent layer is an intermediate layer, the amorphous layer may include an element included in the intermediate layer. For example, when the first adjacent layer is the intermediate layer and the second adjacent layer is the support substrate, the amorphous layer may include an element included in the intermediate layer and an element included in the support substrate. In addition, when the first adjacent layer is the SiO₂-containing substrate and the second adjacent layer is the intermediate layer, the amorphous layer may include an element included in the SiO₂-containing substrate and an element included in the intermediate layer. Further, when the first adjacent layer and the second adjacent layer are intermediate layers, the amorphous layer may include an element included in the intermediate layer serving as the first adjacent layer and an element included in the intermediate layer serving as the second adjacent layer. In addition, the amorphous layer may further include iron and chromium resulting from a joining process of the support substrate and the SiO₂-containing substrate. Typically, the amorphous layer 30 may further include an atom species (typically, argon, neon, krypton, helium, nitrogen, or xenon) for forming a neutral atom beam to be used in the direct joining. The content of such atomic species in the amorphous layer may be, for example, from 1.5 atomic% to 2.5 atomic%.

A thickness of the amorphous layer may be, for example, from 0.1 nm to 100 nm, or for example, from 2 nm to 15 nm.

### E. Intermediate Layer

As described above, the composite wafer may further include the intermediate layer. The intermediate layer may be arranged at any appropriate position. For example, the intermediate layer may be arranged between the support substrate and the amorphous layer, the intermediate layer may be arranged between the amorphous layer and the SiO₂-containing substrate, or the intermediate layers may be arranged between the support substrate and the amorphous layer, and between the amorphous layer and the SiO₂-containing substrate, respectively. The intermediate layer may be formed of any appropriate material. Examples of the material for forming the intermediate layer include tantalum oxide (Ta₂O₅), niobium oxide (Nb₂O₅), titanium oxide (TiO₂), aluminum oxide (Al₂O₃), hafnium oxide, and silicon (e.g., amorphous silicon). Of those, silicon such as amorphous silicon is preferably used.

A thickness of the intermediate layer is, for example, from 5 nm to 1 μm, preferably from 10 nm to 20 nm.

### F. Functional Layer

Any appropriate functional layer may be formed as the functional layer in accordance with applications and functions of the composite wafer. Examples thereof include functional layers formed of silicon nitride (SiN), niobium pentoxide (Nb₂O₅), tantalum pentoxide (Ta₂O₅), aluminum oxide (Al₂O₃), silicon (Si), indium phosphorus (InP), gallium nitride (GaN), aluminum nitride (AlN), silicon carbide (SiC), gallium oxide (Ga₂O₃), gallium arsenide (GaAs), barium titanate (BaTiO₃ (BTO)), sapphire, lead zirconate titanate (PbZrTiO₃ (PZT)), lead lanthanum zirconate titanate (PLZT), gallium phosphide (GaP), and potassium tantalate niobate (KTN). When a SiO₂-containing substrate having a OH group content of 100 ppm or less is used as the SiO₂-containing substrate, examples of the functional layer include functional layers formed of silicon nitride (SiN), niobium pentoxide (Nb₂O₅), tantalum pentoxide (Ta₂O₅), aluminum oxide (Al₂O₃), silicon (Si), indium phosphorus (InP), gallium nitride (GaN), aluminum nitride (AlN), silicon carbide (SiC), gallium oxide (Ga₂O₃), gallium arsenide (GaAs), barium titanate (BaTiO₃ (BTO)), sapphire, lead zirconate titanate (PbZrTiO₃ (PZT)), lead lanthanum zirconate titanate (PLZT), gallium phosphide (GaP), potassium tantalate niobate (KTN), lithium niobate (LN), and lithium tantalate (LT). As described above, the composite wafer of the present disclosure has excellent heat resistance. Accordingly, the functional layer can be formed at higher temperature. When the functional layer is formed at high temperature, a functional layer having higher functionality (e.g., a higher density or a higher purity) can be formed. In addition, occurrence of warpage can be further suppressed in the composite wafer. As a result, the functional layer can also be formed by transfer (rebonding).

The composite wafer having the functional layer may be used for any appropriate application in accordance with the functional layer. Specifically, a composite wafer having a functional layer formed of silicon nitride is suitably used in an optical device. Specific examples thereof include an optical waveguide having a wide wavelength band from visible to infrared regions, an optical comb device using a nonlinear optical effect, and an erbium-doped optical waveguide type optical amplifier.

A composite wafer having a functional layer formed of niobium pentoxide, tantalum pentoxide, aluminum oxide, or sapphire is suitably used in an optical device. A specific example thereof is an optical waveguide having a wide wavelength band from visible to infrared regions.

A composite wafer having a functional layer formed of silicon is suitably used in an electronic device and an optical device. Specific examples of the electronic device include SOI wafers to be used in semiconductors, such as a complementary metal-oxide-semiconductor (CMOS) and a memory. In addition, a specific example of the optical device is use in an optical waveguide device called silicon photonics instead of conventional thermally oxidized silicon. Further, an optical integrated circuit may be formed by forming an optical modulator and a photodiode in silicon.

A composite wafer having a functional layer formed of indium phosphorus or gallium arsenide is suitably used in an electronic device and an optical device. A specific example of the electronic device is use of the SiO₂-containing substrate of the composite wafer as an insulating layer of a transistor capable of high-speed operation. A specific example of the optical device is an optical integrated circuit using the SiO₂-containing substrate of the composite wafer as an insulating layer or a low refractive index layer. A more specific example thereof is an optical integrated circuit in which an optical modulator, a laser, and a photodiode are formed.

A composite wafer having a functional layer formed of gallium nitride and aluminum nitride is suitably used in an electronic device and an optical device. Specifically, the SiO₂-containing substrate of the composite wafer may be used as an insulating layer of a transistor capable of high-speed operation in the electronic device. A specific example of the optical device is an optical integrated circuit using the SiO₂-containing substrate of the composite wafer as an insulating layer or a low refractive index layer. A more specific example thereof is an optical integrated circuit in which an optical modulator, a laser, and a photodiode are formed.

A composite wafer having a functional layer formed of silicon carbide is suitably used in an electronic device and an optical device. Specifically, the SiO₂-containing substrate of the composite wafer may be used as an insulating layer of a transistor capable of controlling large power or capable of high-speed operation in the electronic device. Examples of the optical device include: an optical waveguide having a wide wavelength band from visible to infrared light regions using the SiO₂-containing substrate of the composite wafer as a low refractive index layer; and an optical comb device using a nonlinear optical effect.

A composite wafer having a functional layer formed of gallium oxide is suitably used in an electronic device. An example thereof is a transistor capable of controlling large power or capable of high-speed operation using the SiO₂-containing substrate of the composite wafer as an insulating layer.

A composite wafer having a functional layer formed of barium titanate, lead zirconate titanate, lead lanthanum zirconate titanate, or potassium tantalate niobate is suitably used in an optical device. Examples thereof include an optical modulator capable of operating at a low driving voltage and an optical scanner device each using the SiO₂-containing substrate of the composite wafer as a low refractive index layer.

A composite wafer having a functional layer formed of gallium phosphide is suitably used in an optical device. An example thereof is a device that generates mid-infrared rays or terahertz waves using the SiO₂-containing substrate of the composite wafer as a low refractive index layer.

When a SiO₂-containing substrate having a OH group content of 100 ppm or less is used as the SiO₂-containing substrate, a composite wafer having a functional layer formed of lithium niobate or lithium tantalate is suitably used as an optical device. Examples thereof include an optical modulator capable of operating at a low driving voltage applying an electro-optic effect and an optical scanner device or a wavelength conversion device applying a nonlinear optical effect, each using the SiO₂-containing substrate of the composite wafer as a low refractive index layer.

The functional layer may be preferably laminated on the thin-layer processed surface of the SiO₂-containing substrate. The functional layer may be formed by any appropriate method. The functional layer may be directly formed on the thin-layer processed surface of the SiO₂-containing substrate, or a functional layer formed on any appropriate base material may be transferred (rebonded) to the thin-layer processed surface of the SiO₂-containing substrate. When the functional layer is laminated by rebonding, the SiO₂-containing substrate and the functional layer may be directly joined or may be laminated via any appropriate joining layer.

The thermal expansion coefficient αf of the functional layer 40 may be set to any appropriate value. The thermal expansion coefficient of the functional layer may be set so that the ratio (αf/αg) between the thermal expansion coefficient αf of the functional layer 40 and the thermal expansion coefficient αg of the SiO₂-containing substrate 10 satisfies the relationship of 0.5≤αf/αg≤10. The thermal expansion coefficient αf of the functional layer 40 is preferably from 1 ppm/°C to 17 ppm/°C, more preferably from 1 ppm/°C to 10 ppm/°C, still more preferably from 1.5 ppm/°C to 8 ppm/°C, particularly preferably from 2 ppm/°C to 5 ppm/°C. When the thermal expansion coefficient αf of the functional layer falls within the above-mentioned ranges, a composite wafer having more excellent heat resistance can be provided. For example, thermal expansion coefficients of the materials to be used as the materials for forming the functional layer are as follows: silicon nitride (3 ppm/°C to 3.5 ppm/°C); niobium pentoxide (5.8 ppm/°C); tantalum pentoxide (5 ppm/°C); aluminum oxide (5.3 ppm/°C); silicon (2.6 ppm/°C); indium phosphorus (4.5 ppm/°C); gallium nitride (5.6 ppm/°C); aluminum nitride (4.6 ppm/°C); silicon carbide (4.0 ppm/°C); gallium oxide (2.0 ppm/°C); gallium arsenide (6.0 ppm/°C); barium titanate (5.0 ppm/°C); sapphire (5.5 ppm/°C); lead zirconate titanate (3.4 ppm/°C); lead lanthanum zirconate titanate (5.4 ppm/°C); potassium tantalate niobate (3 ppm/°C); gallium phosphide (5.3 ppm/°C); lithium niobate (5.0 ppm/°C to 16.0 ppm/°C); and lithium tantalate (4.0 ppm/°C to 16.0 ppm/°C). The thermal expansion coefficient of the functional layer may be measured by any appropriate method. For example, the thermal expansion coefficient may be measured with a thermomechanical analyzer (TMA).

A density of the functional layer 40 may be set to any appropriate value. The density of the functional layer is preferably from 1.5 g/cm³ to 7.5 g/cm³, preferably from 1.5 g/cm³ to 6.0 g/cm³, more preferably from 2.0 g/cm³ to 5.0 g/cm³, still more preferably from 2.5 g/cm³ to 4.0 g/cm³. A functional layer having a higher density can be formed because the composite wafer of the embodiment of the present disclosure has excellent heat resistance as described above. For example, densities of the materials to be used as the materials for forming the functional layer are as follows: silicon nitride (3.2 g/cm³); niobium pentoxide (4.47 g/cm³); tantalum pentoxide (8.18 g/cm³); aluminum oxide (3.9 g/cm³); silicon (2.3 g/cm³); indium phosphorus (4.79 g/cm³); gallium nitride (6.15 g/cm³); aluminum nitride (3.26 g/cm³); silicon carbide (3.2 g/cm³); gallium oxide (α: 6.4 g/cm³, β: 5.9 g/cm³); gallium arsenide (5.31 g/cm³); barium titanate (6.0 g/cm³); sapphire (4.0 g/cm³); lead zirconate titanate (7.5 g/cm³); lead lanthanum zirconate titanate (7.6 g/cm³); or potassium tantalate niobate (6.4 g/cm³); gallium phosphide (4.13 g/cm³); lithium niobate (4.65 g/cm³); and lithium tantalate (7.46 g/cm³). The density of the functional layer may be measured by any appropriate method. For example, the density may be measured by density measurement using a pycnometer specified in JIS Z 8807.

The thickness of the functional layer may be set to any appropriate thickness. The thickness of the functional layer is preferably from 0.1 μm to 10 μm, more preferably from 0.3 μm to 2 μm, still more preferably from 0.4 μm to 1 μm. When the thickness of the functional layer falls within the above-mentioned ranges, the effects exhibited by arranging the functional layer can be sufficiently obtained.

### G. Production Method

In another aspect of the present disclosure, a method of producing a composite wafer can be provided. The method of producing a composite wafer of the present disclosure includes directly joining a support substrate and a SiO₂-containing bulk. A composite wafer having more excellent heat resistance can be obtained by directly joining the support substrate and the SiO₂-containing bulk. As described above, when the support substrate and the SiO₂-containing bulk are joined by the direct joining, the amorphous layer may be formed between the support substrate and the SiO₂-containing bulk. In the composite wafer obtained by the production method, the first adjacent layer may be the support substrate, and the second adjacent layer may be the SiO₂-containing substrate. As described later, the SiO₂-containing bulk may function as the SiO₂-containing substrate by being thinned.

Any appropriate bulk is used as the SiO₂-containing bulk as long as the bulk is an integral bulk obtained by crystal growth and/or synthesis, rather than a bulk obtained by film formation. For example, a bulk of each of the materials for forming the SiO₂-containing substrate given as examples in the foregoing may be used. The thickness of the SiO₂-containing bulk may be set to any appropriate thickness. The thickness of the SiO₂-containing bulk is preferably 100 μm or more, more preferably from 200 μm to 1,000 μm, still more preferably from 250 μm to 500 μm. When the thickness of the SiO₂-containing bulk falls within the above-mentioned ranges, the SiO₂-containing bulk can be satisfactorily joined to the support substrate by direct joining. In addition, heat resistance of the composite wafer to be obtained can be improved.

The SiO₂-containing bulk is produced by any appropriate method. Examples thereof include: synthetic methods such as a direct method, a plasma method, a soot method, and a sol-gel method; an oxyhydrogen flame melting method; and an electric melting method. Raw materials may vary in accordance with a method of producing a bulk, and the metal impurity content and OH group content of the SiO₂-containing bulk may vary accordingly, and various characteristics may also vary. For example, when the synthetic method is used, the metal impurity content and the OH group content can be relatively reduced. Specific methods are as described above.

The above-mentioned product may be used as the support substrate. The direct joining between the support substrate and the SiO₂-containing bulk is performed by any appropriate method. Examples thereof include a surface activation method, a plasma method, and an atom diffusion method. In addition, the direct joining may be performed by the following method. Each bonding surface of the support substrate and the SiO₂-containing bulk is irradiated with a neutralized beam in a high vacuum chamber (e.g., about 1×10⁻⁶ Pa). Thus, each joint surface is activated. Next, the activated joint surfaces are brought into contact with each other in a vacuum atmosphere and are joined at normal temperature. A load during the joining may be, for example, from 100 N to 20,000 N. In one embodiment, when surface activation is performed with a neutralized beam, an inert gas is introduced into the chamber, and a high voltage is applied from a DC power source to an electrode arranged in the chamber. With such configuration, electrons move through an electric field generated between the electrode (positive electrode) and the chamber (negative electrode), and a beam of atoms and ions by the inert gas is generated. Of the beams reaching a grid, an ion beam is neutralized at the grid, and hence a beam of neutral atoms is emitted from a fast atom beam source. Atom species for forming the beam are typically argon, neon, krypton, helium, nitrogen, and xenon. A voltage during the activation by beam irradiation is, for example, from 0.5 kV to 2.0 kV, and a current is, for example, from 50 mA to 200 mA. As described above, atoms included in the neutral atom beam may be included in the amorphous layer formed by the direct joining.

A method of producing a composite wafer of another embodiment of the present disclosure includes: forming an

intermediate layer on at least one of a support substrate or a SiO₂-containing bulk; and directly joining: the intermediate layer formed on the support substrate and the SiO₂-containing bulk; the intermediate layer formed on the SiO₂-containing bulk and the support substrate; or the intermediate layer formed on the support substrate and the intermediate layer formed on the SiO₂-containing bulk. Specifically, when the intermediate layer is formed on the support substrate, the intermediate layer formed on the support substrate and the SiO₂-containing bulk are directly joined. In this case, the amorphous layer including an element included in the intermediate layer formed on the support substrate and an element included in the SiO₂-containing bulk may be formed. In the composite wafer obtained by the production method, the first adjacent layer may be the intermediate layer formed on the support substrate, and the second adjacent layer may be the SiO₂-containing substrate. As described later, the SiO₂-containing bulk may function as the SiO²-containing substrate by being thinned. When the intermediate layer is formed on the SiO₂-containing bulk, the intermediate layer formed on the SiO₂-containing bulk and the support substrate are directly joined. In this case, the amorphous layer including an element included in the intermediate layer formed on the SiO₂-containing bulk and an element included in the support substrate may be formed. In the composite wafer obtained by the production method, the first adjacent layer may be the support substrate, and the second adjacent layer may be the

intermediate layer formed on the SiO₂-containing bulk. When the intermediate layer is formed on each of the support substrate and the SiO₂-containing bulk, the intermediate layer formed on the support substrate and the intermediate layer formed on the SiO₂-containing bulk are directly joined. In this case, the amorphous layer including an element included in the intermediate layer formed on the SiO₂-containing bulk and an element included in the intermediate layer formed on the support substrate may be formed. In the composite wafer obtained by the production method, the first adjacent layer may be the intermediate layer formed on the support substrate, and the second adjacent layer may be the intermediate layer formed on the SiO₂-containing bulk. A composite wafer having more excellent heat resistance can be obtained by directly joining: the intermediate layer formed on the SiO₂-containing bulk and the support substrate; the intermediate layer formed on the support substrate and the SiO₂-containing bulk; or the intermediate layer formed on the support substrate and the intermediate layer formed on the SiO₂-containing bulk.

The intermediate layer may be formed by any appropriate method. Examples thereof include: physical vapor deposition, such as sputtering, vacuum deposition, or ion beam assisted deposition (IAD); chemical vapor deposition; and an atomic layer deposition (ALD) method. The intermediate layer may be formed with the heating of the substrate or may be formed without the heating of the substrate. When the substrate is heated, a heating temperature may be, for example, from 100°C to 300°C, and is preferably from 120°C to 250°C, more preferably from 140°C to 200°C. When the intermediate layer is formed between the support substrate and the amorphous layer, the intermediate layer may be formed on the surface of the support substrate to be joined to the SiO₂-containing bulk, and then the above-mentioned direct joining may be performed. In addition, when the intermediate layer is formed between the amorphous layer and the SiO₂-containing substrate, the intermediate layer may be formed on the surface of the SiO₂-containing bulk to be joined to the support substrate, and then the above-mentioned direct joining may be performed. As described above, the intermediate layer may be formed of any appropriate material. Specific examples thereof include tantalum oxide (Ta₂O₅), niobium oxide (Nb₂O₅), titanium oxide (TiO₂), aluminum oxide (Al₂O₃), hafnium oxide, and silicon (e.g., amorphous silicon). The thickness of the intermediate layer is, for example, from 5 nm to 1 μm, preferably from 10 nm to 200 nm.

The direct joining between the intermediate layer formed on the support substrate and the SiO₂-containing bulk, the direct joining between the intermediate layer formed on the SiO₂-containing bulk and the support substrate, or the direct joining between the intermediate layer formed on the support substrate and the intermediate layer formed on the SiO₂-containing bulk is performed by any appropriate method. Specific examples thereof include the above-mentioned methods.

The SiO₂-containing bulk directly joined to the support substrate is preferably thinned to produce a SiO₂-containing substrate. Typically, the thickness of the bulk is larger than the thickness of the SiO₂-containing substrate that may be formed on the composite wafer. The thickness may be adjusted to such a thickness that the substrate can be suitably used in the composite wafer by the thinning. The thinning may be performed by any appropriate method. For example, the SiO₂-containing substrate may be produced by polishing the surface of the SiO₂-containing bulk free from being directly joined to the support substrate through use of any appropriate abrasive and thinning the bulk to a predetermined thickness. In addition, the thinning may be performed by smart cutting. The smart cutting is a method well-known as a method of thinning a silicon substrate. Specifically, hydrogen ions are injected into silicon to form a microvoid layer at a position of 1 μm or less from a surface. Next, the thinning may be performed by growing voids and cleaving the silicon by heat treatment at from 100°C to 500°C.

The method of producing a composite wafer of the embodiment of the present disclosure preferably further includes laminating a functional layer on the SiO₂-containing substrate. The laminate (composite wafer) directly joined in the above-mentioned process has excellent heat resistance. More specifically, warpage and breakage of the composite wafer can be suppressed even when the composite wafer is subjected to treatment at high temperature. Accordingly, when the functional layer is arranged by direct formation, the functional layer can be formed at a higher temperature such as 400°C or more. As a result, a functional layer having higher functionality (e.g., a higher density and a higher purity) can be formed. When the functional layer is arranged by the direct formation, a formation temperature is preferably 850°C or less, more preferably 800°C or less, particularly preferably 700°C or less. For example, when the functional layer is formed by using silicon nitride, the functional layer may be formed by direct formation on the SiO₂-containing substrate. In this embodiment, a functional layer formed of silicon nitride may be formed at, for example, from 400°C to 800°C. In addition, the functional layer can be formed on the SiO₂-containing substrate by using a material that has heretofore been difficult to directly form on a composite wafer.

In another embodiment, the functional layer may be formed by transferring (rebonding) a functional layer formed on any appropriate base material onto the SiO₂-containing substrate. A functional layer is generally a hard layer, and hence, when warpage occurs on a bonding surface of the composite wafer, it may become difficult to bring a bonding surface of the functional layer and a bonding surface of the SiO₂-containing substrate into sufficiently close contact with each other. Accordingly, even when directly joined or laminated by via any appropriate joining layer, the functional layer may peel from the SiO₂-containing substrate, and sufficient durability may not be obtained. The bonding surface of the functional layer and the bonding surface of the SiO₂-containing substrate can be brought into sufficiently close contact with each other because warpage is suppressed in the composite wafer obtained by the production method of the embodiment of the present disclosure. Further, when a thin-layer processed surface is formed by polishing or the like, smoothness of the thin-layer processed surface is improved, and hence adhesiveness can be further improved. In addition, a composite wafer in which the respective layers are brought into closer contact with each other can be obtained by the direct joining or the lamination via any appropriate joining layer. In this embodiment, the base material used for forming the functional layer may be peeled and removed after rebonding to the SiO₂-containing substrate, may be removed by any appropriate treatment such as polishing, or may be used as it is as a layer for forming the composite wafer.

The above-mentioned methods are each used as a method for the direct joining. In addition, when the SiO₂-containing substrate and the functional layer are laminated via the joining layer, the layers may be laminated via any appropriate joining layer in accordance with a material for the functional layer. Examples thereof include tantalum oxide (Ta₂O₅), niobium oxide (Nb₂O₅), titanium oxide (TiO₂), aluminum oxide (Al₂O₃), hafnium oxide, and silicon (e.g., amorphous silicon). The thickness of the joining layer is, for example, from 5 nm to 1 μm, preferably from 10 nm to 200 nm.

The joining layer may be formed by any appropriate method. For example, the joining layer may be formed by: physical vapor deposition, such as sputtering, vacuum deposition, or ion beam assisted deposition (IAD); chemical vapor deposition; or an atomic layer deposition (ALD) method. The formation of the joining layer may be performed at, for example, from 100°C to 300°C, preferably from 120°C to 250°C, more preferably from 140°C to 200°C. The formation of the joining layer may be performed at room temperature. The lamination of the functional layer by rebonding may be suitably used when each of semiconductors, such as Si and SiC, or ceramics, such as BTO and PZT, is used as a material for forming the functional layer.

### Examples

The present disclosure is specifically described below by way of Examples. However, the present disclosure is not limited to these Examples.

### Example 1

### 1. Production of Composite Wafer

A composite wafer in which a silicon wafer, a synthetic quartz glass wafer (OH group concentration: 15 ppm), and an X-cut LN wafer were joined was produced.

Specifically, first, surfaces of a silicon wafer (4 inches, resistivity: 10 k·Ωcm or more, thickness: 525 μm) and a synthetic quartz glass bulk (4 inches, thickness: 500 μm, OH content: 15 ppm) were each subjected to high-flatness polishing processing so as to have an arithmetic average surface roughness Ra of 0.2 nm. Next, the surfaces each subjected to the polishing processing were joined by a wafer surface activation method. Specifically, the silicon wafer and the synthetic quartz glass bulk were loaded into a vacuum chamber, and joining surfaces of the silicon wafer and the synthetic quartz glass bulk were irradiated with a fast Ar neutral atom beam (acceleration voltage: 1 kV, Ar flow rate: 60 sccm) for 70 seconds in a vacuum on the order of 10 ⁻⁶ Pa. After the irradiation, the wafers were left to stand for 10 minutes to be cooled. A beam irradiation surface of the silicon wafer and a beam irradiation surface of the synthetic quartz glass bulk were brought into contact with each other, and pressurization was performed at 4.90 kN for 2 minutes to join the silicon wafer and the synthetic quartz glass bulk.

After that, the synthetic quartz glass bulk was ground by precision polishing processing so that the thickness of the synthetic quartz glass bulk became 2 μm. Thus, a synthetic quartz glass wafer (SiO₂-containing substrate) having an arithmetic average surface roughness Ra of 0.2 nm on its surface was obtained.

Separately, an X-cut LN wafer was subjected to high-flatness polishing processing so as to have an arithmetic average surface roughness Ra of 0.2 nm on its surface. Next, the synthetic quartz glass wafer of the wafer in which the silicon wafer and the synthetic quartz glass wafer were joined, and the LN wafer were joined by a plasma activation method.

After that, precision polishing processing was performed on the LN wafer side of the laminate of the LN wafer, the synthetic quartz glass wafer, and the silicon wafer thus joined to set a thickness of the LN to 600 nm. Thus, a composite wafer was obtained. An amorphous layer was formed between the silicon wafer and the synthetic quartz glass wafer.

### 2. Formation of Optical Waveguide

Diamond-like carbon (DLC) was formed to a thickness of 300 nm by plasma-enhanced chemical vapor deposition (plasma-enhanced CVD, PECVD) on the LN wafer side of the composite wafer of the LN wafer, the synthetic quartz glass wafer, and the silicon wafer. Next, a resist was applied, and a resist pattern for forming an optical waveguide was formed by photolithography. After that, reactive ion etching was performed in oxygen plasma through use of the resist pattern as a mask to etch the DLC. Further, dry etching was performed in Ar gas through use of the DLC as a hard mask to etch the LN wafer by 400 nm to form a ridge-type optical waveguide. At this time, a width at a surface of the ridge waveguide was 1.5 μm, and the remaining thickness of the LN wafer at an etched part was 200 nm. Three kinds of optical waveguides having lengths of 10 mm, 20 mm, and 30 mm were formed. After that, the remaining DLC pattern was removed by etching. Thus, the process was completed.

### 3. Optical Evaluation

The composite wafers on which the optical waveguides were formed were cut into lengths of 10 mm, 20 mm, and 30 mm by dicing to provide optical waveguide devices, and both end surfaces of each of the optical waveguide devices were subjected to end surface polishing.

The optical waveguide device was coupled to a lensed fiber, and an optical insertion loss was measured for each device. Specifically, light was introduced into the optical waveguide device through an input-side lensed fiber coupled to an optical fiber, and an amount of light output through an output-side lensed fiber was measured with a photodetector to calculate a propagation loss. Evaluation was performed by using lasers having wavelengths of 1.31 μm, 1.48 μm, 1.55 μm, and 1.61 μm. Length dependence was evaluated in optical insertion loss data with different device lengths, and a light propagation loss was calculated from a slope thereof. As a result of the measurement, the light propagation loss was from 0.05 dB/cm to 0.1 dB/cm at the above-mentioned wavelengths.

### Comparative Example

### 1. Formation of Composite Wafer

A composite wafer in which a silicon wafer, a sputtered SiO₂ film, and an X-cut LN wafer were joined was produced.

Specifically, a silicon wafer (4 inches, resistivity: 10 k·Ωcm or more, thickness: 525 μm) was subjected to high-flatness polishing processing so as to have an arithmetic average surface roughness Ra of 0.2 nm on its surface in the same manner as in Example.

Next, SiO₂ was formed to a thickness of 2 μm on a surface of the silicon wafer with a sputtering apparatus. After that, a surface of the SiO₂ film was subjected to precision polishing processing so as to have an arithmetic average surface roughness Ra of 0.2 nm.

Separately, an X-cut LN wafer was subjected to high-flatness polishing processing so as to have an arithmetic average surface roughness Ra of 0.2 nm on its surface. Next, the SiO₂ film side of the silicon wafer on which the SiO₂ film was formed and the LN wafer were joined by a plasma activation method. Precision polishing processing was performed on the LN wafer side of the laminate of the joined LN wafer, SiO₂ film, and silicon wafer to set the thickness of the LN wafer to 600 nm. Thus, a composite wafer was obtained.

After that, an optical waveguide pattern was formed on the obtained composite wafer in the same manner as in Example. Next, a light propagation loss was calculated by the same method as in Example. As a result, the light propagation loss was from 0.3 dB/cm to 0.4 dB/cm at wavelengths of 1.31 μm, 1.48 μm, 1.55 μm, and 1.61 μm.

The composite wafer of the embodiment of the present disclosure can be suitably used in a semiconductor, an electronic device, an optical device, and the like.

What is claimed is:

1. A composite wafer, comprising in this order:
a support substrate;
an amorphous layer; and
a SiO₂-containing substrate,
wherein the amorphous layer is in contact with a first adjacent layer and a second adjacent layer, and includes an element included in each of the first adjacent layer and the second adjacent layer.

2. A composite wafer, comprising in this order:
a support substrate;
an amorphous layer; and
a SiO₂-containing substrate having a OH group content of 100 ppm or less,
wherein the amorphous layer is in contact with a first adjacent layer and a second adjacent layer, and includes an element included in each of the first adjacent layer and the second adjacent layer.

3. The composite wafer according to claim 1,
wherein the first adjacent layer is the support substrate, and
wherein the second adjacent layer is the SiO₂-containing substrate.

4. The composite wafer according to claim 1, further comprising an intermediate layer, wherein at least one of the first adjacent layer or the second adjacent layer is the intermediate layer.

5. The composite wafer according to claim 1, wherein the SiO₂-containing substrate has a thickness of 5 μm or more.

6. The composite wafer according to claim 1, wherein the support substrate is at least one kind selected from the group consisting of: silicon; indium phosphorus; gallium nitride; gallium arsenide; aluminum nitride; and diamond.

7. The composite wafer according to claim 1, wherein the SiO₂-containing substrate is formed of synthetic quartz glass, quartz glass, oxynitride glass, borosilicate glass, soda-based glass, or crystal.

8. The composite wafer according to claim 1, wherein the SiO₂-containing substrate has a thin-layer processed surface on a surface opposite to a surface joined to the support substrate.

9. The composite wafer according to claim 8, further comprising a functional layer laminated on the thin-layer processed surface of the SiO₂-containing substrate.

10. The composite wafer according to claim 9, wherein the functional layer is formed of at least one kind selected from the group consisting of: silicon nitride; niobium pentoxide; tantalum pentoxide; aluminum oxide; silicon; indium phosphorus; gallium nitride; aluminum nitride; silicon carbide; gallium oxide; gallium arsenide; barium titanate; sapphire; lead zirconate titanate; lead lanthanum zirconate titanate; gallium phosphide; and potassium tantalate niobate.

11. The composite wafer according to claim 2, wherein the SiO₂-containing substrate is at least one kind selected from the group consisting of: synthetic quartz glass; fused quartz glass; and sol-gel glass.

12. The composite wafer according to claim 2, wherein the SiO₂-containing substrate has a thin-layer processed surface on a surface opposite to a surface joined to the support substrate.

13. The composite wafer according to claim 12, further comprising a functional layer laminated on the thin-layer processed surface of the SiO₂-containing substrate.

14. The composite wafer according to claim 13, wherein the functional layer is formed of at least one kind selected from the group consisting of: silicon nitride; niobium pentoxide; tantalum pentoxide; aluminum oxide; silicon; indium phosphorus; gallium nitride; aluminum nitride; silicon carbide; gallium oxide; gallium arsenide; barium titanate; sapphire; lead zirconate titanate; lead lanthanum zirconate titanate; gallium phosphide; potassium tantalate niobate; lithium niobate; and lithium tantalate.

15. The composite wafer according to claim 1, wherein a thermal expansion coefficient αs of the support substrate and a thermal expansion coefficient αg of the SiO₂-containing substrate satisfy a relationship of 0.05≤αg/αs≤1.5.

16. The composite wafer according to claim 10, wherein a thermal expansion coefficient αg of the SiO₂-containing substrate and a thermal expansion coefficient αf of the functional layer satisfy a relationship of 0.5≤αf/αg≤10.

17. A method of producing a composite wafer, the method comprising directly joining a support substrate and a SiO₂-containing bulk.

18. A method of producing a composite wafer, the method comprising:
forming an intermediate layer on at least one of a support substrate or a SiO₂-containing bulk; and
directly joining:
the intermediate layer formed on the support substrate and the SiO₂-containing bulk;
the intermediate layer formed on the SiO₂-containing bulk and the support substrate; or
the intermediate layer formed on the support substrate and the intermediate layer formed on the SiO₂-containing bulk.

19. The method of producing a composite wafer according to claim 17, further comprising producing a SiO₂-containing substrate by thinning the SiO₂-containing bulk joined to the support substrate.

20. The method of producing a composite wafer according to claim 17, wherein the SiO₂-containing bulk has a thickness of 100 μm or more.
